(19) United States
(12) Patent Application Publication
(10) Pub. No.: US 2017/0294291 A1
(43) Pub. Date: Oct. 12, 2017

(54) APPLICATION OF eBIP TO INSPECTION, TEST, DEBUG AND SURFACE MODIFICATIONS

(71) Applicants: ORBOTECH LTD., Yavne (IL); PHOTON DYNAMICS, INC., San Jose, CA (US)

(72) Inventors: Nedal SALEH, Santa Clara, CA (US); Unit B STERLING, San Jose, CA (US); Daniel TOET, Monte Sereno, CA (US); Arie GLAZER, Mevaseret (IL); Ronen LOEWINGER, San Francisco, CA (US); Sriram KRISHNASWAMI, Saratoga, CA (US)

(21) Appl. No.: 15/512,529

(22) PCT Filed: Sep. 17, 2015
(86) PCT No.: PCT/US2015/050777

§ 371 Date: Mar. 17, 2017

Related U.S. Application Data
(60) Provisional application No. 62/051,871, filed on Sep. 17, 2014.

(51) Int. Cl. H01J 37/32

(52) U.S. Cl. CPC H01J 37/32825

(57) ABSTRACT

An electron-beam induced plasma is utilized to establish a non-mechanical, electrical contact to a device of interest. This plasma source may be referred to as atmospheric plasma source and may be configured to provide a plasma column of very fine diameter and controllable characteristics. The plasma column traverses the atmospheric space between the plasma source into the atmosphere and the device of interest and acts as an electrical path to the device of interest in such a way that a characteristic electrical signal can be collected from the device. Additionally, by controlling the gases flowing into the plasma column the probe may be used for surface modification, etching and deposition.

### CROSS-REFERENCES TO RELATED APPLICATIONS

The present application claims priority benefit from U.S. Provisional Application, Ser. No. 62/051,871, filed on Sep. 17, 2014, which claims priority benefit from U.S. Provisional Application, Ser. No. 61/886,625, filed on Oct. 3, 2013, and is also relates to PCT application number WO2013/012616, filed Jul. 10, 2012, entitled “ELECTRICAL INSPECTION OF ELECTRONIC DEVICES USING ELECTRON-BEAM INDUCED PLASMA PROBES”, the content of both of which is incorporated herein by reference in its entirety.

### BACKGROUND

### 1. Field

Various embodiments of the present invention generally relate to the non-mechanical contact probing of electronic devices and surface modification of devices and tissue. In particular, the various embodiments relate to application of electron-beam induced plasma probes for metrology and surface modification.

### 2. Related Arts

The ability to measure and apply voltages and currents on patterned structures without having to establish mechanical contact is of importance to the functional (electrical) testing of semiconductor devices and flat panel displays, e.g., liquid crystal and organic light emitting diode (OLED) displays, backplanes, and printed circuit boards, since non-mechanical contact probing minimizes the likelihood of damage to the device/panel under test and is also conducive to improved testing throughput.

Photon Dynamics’, an Orbotech company Voltage Imaging® optical system (VIOS) employs electro-optical transducers to translate the electrical fields on the devices under test into optical information captured by an optical sensor. Other techniques provide an indirect measurement of the voltage on the devices under test by means of secondary electrons and require the devices to be placed in vacuum. These approaches are mostly geared towards voltage measurements and still require mechanical contacts to pads on the periphery of the devices in order to drive the signals used for inspection.

The need for a non-mechanical probe emerged as a new class of current-driven devices such as OLEDs was developed. As opposed to voltage-driven devices such as conventional LCDs, the preferred way of testing OLED-based flat panel displays after array fabrication is by allowing a current to pass through the unsealed pixel electrode in a non-destructive fashion, especially in those OLED architectures in which the cell holding capacitance is small. A separate class of inspection methods based on conductive plasmas has recently emerged. The main concept behind these methods is that a directional plasma, which contains mobile secondary electrons besides stationary ions, may act as a non-mechanical contact probe. Several such “plasma probing” approaches have been proposed in the past. They may roughly be divided into two categories, one category being based on high intensity laser-induced ionization, which presents possible risks of laser-induced damage to the device under tests given the high ionization thresholds, and another category being based on high voltage corona discharges, in which ionized species have a wide range of scattering angles (little directional control) and also presents damage risks, especially related to arcing.

Electron beam imaging systems using membranes and differentially pumped apertures have been used to propagate e-beams into a gas ambient for electron beam characterization of live/wet specimens in scanning electron microscopes (SEM) or X-ray diffraction on live samples.

State-of-the-art electron-beam based inspection and registration systems used in semiconductor manufacturing mostly rely on secondary electron (SE) and/or backscattered electron (BSE) imaging in vacuum. This technology involves large vacuum enclosures and complex electron optics, leading to high system costs, large factory foot prints and potentially impacting throughput. Examples of electron beam applications used in semiconductor manufacturing include Voltage Contrast measurements using SE for via short inspection (at some process steps in the IC fabrication process), high aspect ratio feature (e.g. deep trenches and through-silicon vias (TSV)) imaging and sample registration with backscattered electrons.

In the previously filed PCT application number WO2013/012616, an atmospheric plasma prober, for testing of flat panel displays is described. Further work led to the development of additional applications, detailed herein, that may use the same or a similar plasma prober.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Various disclosed embodiments utilize electron-beam induced plasmas (eBIP) to establish a non-mechanical, electrical contact to a device of interest. This plasma source may be referred to as atmospheric plasma source and may be configured to provide a plasma column of very fine diameter and controllable characteristics. The plasma column traverses the atmospheric space between the plasma source into the atmosphere (membrane or pinhole) and the device of interest and acts as an electrical path to the device of interest in such a way that a characteristic electrical signal can be collected from the device. Additionally, by controlling the gases flowing into the plasma column the probe may be used for surface modification, etching and deposition.

In various disclosed embodiments the electron beam and the generated plasma are used for multiple functions. For example, the electron beam is used both to generate and sustain the plasma and also to stimulate a sample of interest, e.g., to generate electron-hole pairs inside the sample. Then, the conductive plasma sustained by the driving electron beam is used to pass an electrical signal to an external measurement apparatus, thus providing a sensor for the amount of current generated by the stimulus of the electron beam. Using this method, stimulus and sensing is done in situ, i.e., the current is collected at the exact point where it is generated, forming a closed-loop operation.

According to disclosed aspects an atmospheric plasma apparatus is provided, comprising: a vacuum enclosure having an orifice at a first side thereof; an electron source positioned inside the vacuum enclosure and having an electron extraction opening; an extractor positioned at the vicinity of the extraction opening and configured to extract electrons from the electron source so as to form an electron beam and direct the electron beam through the orifice, wherein the electron bean is configured to have a diameter smaller than diameter of the orifice; an aperture plate positioned so as to cover the orifice, the aperture plate being electrically conductive and having a conductive line attached thereto, and wherein the aperture plate has an aperture of diameter smaller than the diameter of the electron beam such that the aperture plate reduces the diameter of the electron beam as it passes through the aperture; and, wherein the electron beam is configured to ionize the atmosphere as it exits the aperture so as to sustain a column of plasma.

According to further aspects, a method for performing voltage contrast imaging of a sample is provided, comprising: extracting an electron beam from an electron source in a vacuum enclosure; transmitting the electron beam from the vacuum enclosure into an adjacent ambient gas to thereby ionize gas molecules around the electron beam to generate a column of ionized species; scanning the electron beam over a selected area of a sample located opposite the entry point of the electron beam into the gas ambient; applying a voltage potential across the plasma so as to drive an electron current from the sample to a pick-up electrode; measuring the amount of electron current flowing between the pick-up electrode and the sample; and generating an image using the amount of electron current measured at each location on the selected area and displaying the image on a monitor. The method may further include a step of using the image or the measured current to detect defects in the sample.

According to other disclosed aspects a method is provided for performing dimensional registration using an electron-beam induced plasma probe, comprising: extracting an electron beam from an electron source in a vacuum enclosure; transmitting the electron beam from the vacuum enclosure in to an adjacent gas ambient to thereby ionize gas molecules around the electron beam to generate a column of ionized species, thereby defining a plasma probe; scanning the plasma probe over a selected area of a sample located opposite the entry point of the electron beam into the gas ambient; applying a voltage potential across the plasma so as to drive an electron current from the sample to a pick-up electrode; measuring the amount of electron current flowing between the pick-up electrode and the sample; and using the measurement of the electron current to determine the vertical registration of the plasma prober. The method may further include measuring back scattered electrons scattered from the sample and using the measurement of back scattered electrons to determine lateral registration of the plasma probe, thereby providing three-dimensional registration. In some aspects the registration is used for performing LED, OLED or LCD Array testing.

According to yet further aspects, a method is provided for inspecting material composition profile of a sample using electron beam induced plasma probes, comprising: extracting an electron beam from an electron source in a vacuum enclosure; transmitting the electron beam from the vacuum enclosure in to an adjacent gas ambient to thereby ionize gas molecules around the electron beam to generate a column of ionized species defining a plasma probe; scanning the plasma probe over a selected area of a sample located opposite the entry point of the electron beam into the gas ambient; applying a voltage potential across the plasma so as to drive an electron current from the sample to a pick-up electrode; measuring amount of electron current flowing from the pick-up electrode into the sample or vice-versa; de-convolving changes in the measurement of the electron current caused by topographical features of the sample; using the de-convolved changes in the measured electron current to determine changes in material composition of the sample.

In other aspects, a method is provided for measuring topography of a sample using electron-beam plasma prober, comprising: extracting an electron beam from an electron source in a vacuum enclosure; transmitting the electron beam from the vacuum enclosure in to an adjacent gas ambient to thereby ionize gas molecules around the electron beam to generate a column of ionized species defining a plasma probe; scanning the plasma probe over a selected area of a sample located opposite the entry point of the electron beam into the gas ambient; applying a voltage potential across the plasma so as to drive an electron current from the sample to a pick-up electrode; measuring the amount of electron current flowing from the pick-up electrode into the sample or vice-versa; de-convolving changes in the measurement of the electron current caused by material composition of the sample; using the de-convolved changes in the measured electron current to determine changes in topography of the sample.

According to further aspects, a method for inspecting high aspect ratio structures in a sample is provided, comprising: extracting an electron beam from an electron source in a vacuum enclosure; transmitting the electron beam from the vacuum enclosure in to an adjacent gas ambient to thereby ionize gas molecules around the electron beam to generate a column of ionized species defining plasma probe; scanning the plasma probe over a selected area of a sample located opposite the entry point of the electron beam into the gas ambient; scanning the plasma probe over a selected area of the sample over the high aspect ratio structure; applying a voltage potential across the plasma so as to drive an electron current from the sample to a pick-up electrode; measuring amount of electron current flowing from the pick-up electrode into the sample or vice-versa; generating an image using the amount of electron current measured at each pixel over the selected area and displaying the image on a monitor. The method may further include a step of detecting defects or process deviations in the inspected high aspect ratio structures based on the measured currents.

Other aspects provide a method for performing atmospheric electron beam induced current measurement of embedded defects in a sample, comprising: extracting an electron beam from an electron source; transmitting the electron beam from the vacuum enclosure in to an adjacent gas ambient to thereby ionize gas molecules around the electron beam to generate a column of ionized species; scanning the electron beam over a selected area of the sample located opposite the entry point of the electron beam into the gas ambient so as to generate electron-hole pairs in the sample; using the column of plasma probe to collect current from the sample; and, measuring the amount of current flowing from the sample. The method may further include controllably injecting gas into the plasma.

According to further aspects, a method for neuron excitation is provided, comprising: extracting an electron beam having a defined diameter from an electron source; transmitting the electron beam from the vacuum enclosure in to an adjacent gas ambient to thereby ionize gas molecules around the electron beam to generate a column of ionized species; directing the ionized species onto selected neurons.

A further aspect provides a method for 3D printing of metals, comprising: extracting an electron beam up to 10's of keV of energy having a defined diameter from an electron source; transmitting the electron beam from the vacuum enclosure into an adjacent gas ambient to thereby ionize gas molecules around the electron beam to generate a column of ionized species defining a plasma probe; using the plasma to prepare a surface for applications; melting a metal using sputtered metal particles or thin metal wire using the primary electron beam to deposit a layer based on a pre-designed pattern; repeating the process above to perform printing action over an extended area and multiple vertical layers. The electron beam may be scanned using electromagnetic lens or a moving stage. The system may be connected to and controlled by CAD capable computer. The method may include directing the ionized species over selected area of a printed sample to thereby adhere the additive elements to the printed sample.

According to yet further aspects, methods for treatment of live tissue are provided, comprising: extracting an electron beam having a defined diameter from an electron source; transmitting the electron beam from the vacuum enclosure into an adjacent gas ambient to thereby ionize gas molecules around the electron beam to generate a column of ionized species; manipulating the lateral dimension of the electrons beam as it exist into the gas ambient; directing the plasma ionized species over selected area of the live tissue. The treatment may comprise one of therapeutic application, sterilization, decontamination, wound healing, blood coagulation, cancer cell treatment.

Other aspects include methods for modifying surface characteristics of a sample, comprising: extracting an electron beam having a defined diameter from an electron source; transmitting the electron beam from the vacuum enclosure in to an adjacent gas ambient to thereby ionize gas molecules around the electron beam to generate a column of ionized species forming a plasma probe; manipulating lateral dimension of the electrons beam as it exist into the gas ambient; scanning the plasma probe over selected area of the sample so as to modify the surface characteristics of the sample. The surface modification may comprise one of ashing, etching, surface activation, passivation, wetting, and functionalization

In any of the disclosed embodiments, the ambient gas may comprise air or a mix of one or more inert gasses. Also, transmitting the electron beam from the vacuum enclosure may comprise passing the electron beam a via pinhole provided in an aperture plate separating the vacuum environment from the ambient gas. Transmitting the electron beam from the vacuum enclosure may further comprise passing the electron beam through a membrane prior to passing the electron beam through the pinhole. A voltage potential may be applied to at least one of the sample, the aperture plate or the membrane. The aperture plate or the membrane may comprise a pick-up electrode. The methods may further comprise the use of electron beam and/or plasma for sensing before interaction with or modifying the sample; then processing, interacting or modifying the sample, then sensing again after the processing, interaction or modifying the sample. As such, the methods establish closed-loop processing (sense-process-sense).

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a schematic and cross sectional view of a non-mechanical contact signal measurement apparatus, in accordance with a first embodiment of the present invention.

FIGS. 2 and 2A are schematic diagrams illustrating a method for voltage contrast inspection.

FIG. 3 is a schematic diagram illustrating a method for high aspect ratio holes and trenches inspection.

FIGS. 4 and 4A are schematic diagrams illustrating a method for 3-d registration.

FIG. 5 is a schematic diagram illustrating a method for electron beam induced current (EBIC).

FIG. 6 is a schematic that illustrates the operation of a pinhole for controlling the diameter of the electron beam in the atmosphere.

FIG. 7 is a schematic illustrating an apparatus according to one embodiment utilizing the pinhole.

FIG. 8 is a schematic illustrating another apparatus according to another embodiment utilizing the pinhole.

FIG. 9 illustrates a top view of a pinhole aperture plate that can be used in any of the embodiments described herein. As shown, the aperture plate has a small pinhole, and an electrical isolation is provided to divide the plate into four quadrants.

FIG. 10 illustrates a top view of a pinhole aperture plate that can be used in any of the embodiments described herein. As shown, the aperture plate has a small pinhole, and an electrical isolation is provided to divide the plate into concentric electrically isolated circular sectors.

FIG. 11 is an illustration of the use of e-beam induced plasma probes for 3D printing. A feed wire supplies the material to be printed; the primary beam melts the wire and the plasma current can be used to sense the printed material.

FIG. 12 is an illustration of the use of e-beam induced plasma probes for spatially selective surface modifications (activation, wetting, functionalization, etc.).

FIG. 13 is an illustration of the use of e-beams for therapeutic applications.

FIG. 14 is an illustration of the use of e-beams for embedded (i.e., sub-surface) micro-channels.

FIG. 15 is a view showing an embodiment for obtaining optimal capillary fluid flow in embedded micro-channels, by eBIP process following a pattern matching the one on the bottom substrate.

FIG. 16 illustrates electron beam system that includes a stage assembly that moves the device under process laterally relative to the e-beam induced plasma.

FIG. 17 illustrates a system having a final open aperture and multiple chambers that are differentially pumped to keep the pressure inside the gun system at the requisite operational level.

FIGS. 18A and 18B illustrate a simple microchannel substrate for flowing fluids therein.

FIGS. 19A and 19B illustrate a test done of a flat substrate having no channels cut therein, resulting in different contact angles (CA).

FIGS. 20A and 20B illustrate a microchannel device wherein a physical channel is formed, and then treated using the eBIP.

FIGS. 21A and 21B illustrate an embodiment wherein “virtual” channels are formed.

FIG. 22 illustrates another microchannel device having a single point of fluid injection and a plurality of channels.

### DETAILED DESCRIPTION

Various embodiments described below provide solutions based on a high resolution, high sensitivity, and compact atmospheric electron beam induced plasma probe technology. This technology essentially relies on the fact that the plasma generated by collisional ionization events driven by the electron beam in air acts as a non-mechanical conductive contact, allowing voltages on the devices under test (DUT) to be measured via the resulting secondary plasma electron current. As implied by the name, this technology does not require the DUT to be held in vacuum. Rather, only the electron emitter (cathode) and electron optics need to be kept in a vacuum enclosure. Furthermore, the implementation of this technology only requires simple electron optics configurations, e.g. an extraction grid and an electrostatic lens, keeping the gun cost low and its size, and hence the size of the enclosure, compact. The electron beam exits the vacuum enclosure containing the electron gun into the surrounding atmospheric environment either by means of a thin, electron transparent-membrane (SiN, SiC, Be, etc.) and/or a microscopic pinhole subjected to differential pumping. The signal carried by the mobile secondary electrons in the plasma probe can be picked up by a conductive thin film (Ti, Cr, etc. of thickness up to 20 nm) applied to the side of the membrane facing the DUT or, in case a pinhole is used, the pinhole itself (assuming it is made of conductive material and isolated from the rest of the electron gun enclosure). From there, the signal is fed to the appropriate acquisition device, e.g. a high precision, high speed electrometer for further signal processing.

Without any loss of novelty or practicality of this invention, the spatial resolution required for the various applications listed below can be also achieved by using a small diameter e-beam emitter and highly focusing e-beam column. While this approach may add to the system cost, it still offers differential advantage over systems requiring vacuum and load-lock sample enclosures. The physics associated with the plasma probe to implement the applications described herein is independent of the method by which the final e-beam spot is generated.

However, the simplest approach to generate a high-resolution final e-beam spot is to aperture the output e-beam using a pinhole. This approach decouples the electron beam diameter from the beam energy, thereby reducing the need for high-end electron optics to achieve small and stable focal spots and offering more potential for system compactness. Moreover, the pinhole can serve as a biasing and signal collection electrode and it can allow the use of higher incident electron beam currents than a stand-alone membrane. Furthermore, an adequately thick pinhole can be sectioned into 4 isolated quadrants to allow for beam deflection control. This aperture can be implemented in such a way that it may be attached to the membrane, or on a secondary chamber.

The edges of the pinhole should be thick enough to stop the incident primary e-beam so that a top-hat beam profile is formed. This in turn produces a plasma probe with well-defined edges minimizing skin-depth and cross-talk from arrayed targets. Furthermore, the pinhole should be adequately smaller than the incident e-beam, as well have a conductive surface, in order to that it contacts the plasma wire produced on the air side of cathode chamber. It should also be substantially thick: (typically >50 micron) to allow for an enameled wire to be attached to its edge and to prevent charge accumulation. Finally, it should be electrically insulated from chamber body; i.e., it should not short to ground.

In order to better understand the various embodiments described below, a brief description of the atmospheric electron-beam induced plasma source will first be provided. Electron beams can provide efficient ionization of air or other gasses, and generate highly directional plasma columns with little risk of damage to the device under test (hereinafter alternatively referred to as structure under test). Electron beams also may provide control of the lateral size of the plasma probe, which is an important advantage for the measurement of electrical signals on small, high-density conductors on the device.

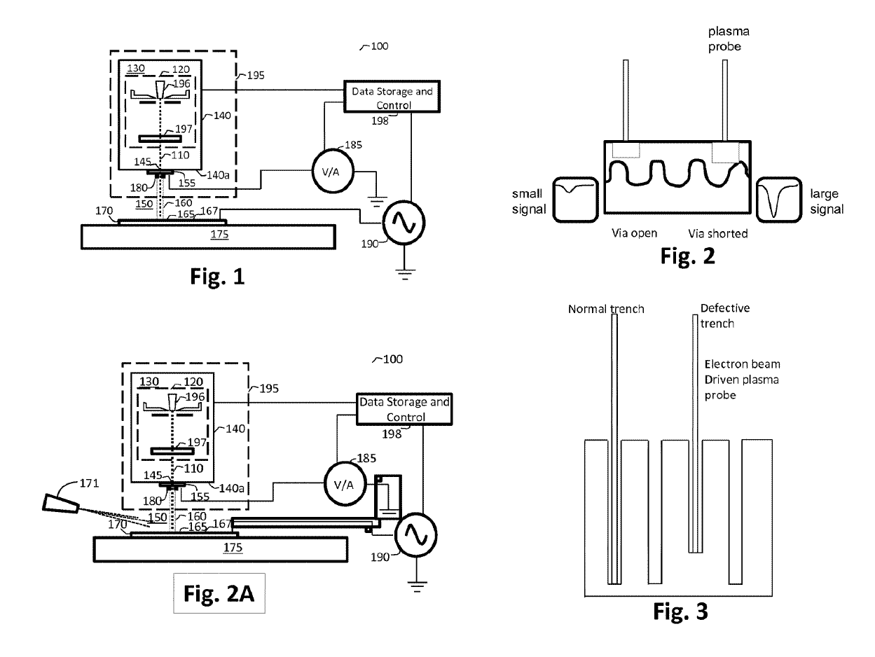

FIG. 1 is a schematic and cross sectional view of a non-mechanical contact signal measurement apparatus 100, in accordance with a first embodiment of the present invention. An electron beam 110 is generated by an electron beam generator 120 in a vacuum 130 using conventional methods. Electron beam 110 egresses a vacuum enclosure 140 (hereinafter alternatively referred to as vacuum chamber) through an orifice 145 located in a portion of the vacuum enclosure 140a. A portion of the electron beam is passed to an ambient gas 150 (hereinafter alternatively referred to as ambient or gas) outside the vacuum enclosure. The vacuum inside the vacuum enclosure containing the electron beam generator can be preserved by a membrane and frame assembly 155 that is semi-transparent to the electron beam.

Alternatively, membrane and frame assembly 155 may be optional when the orifice or multiplicity of orifices is small enough to preserve the vacuum inside the vacuum enclosure.

Upon entering the ambient gas, the electrons in the portion of the electron beam directed into the gas collide with the gas atoms and are deflected or lose energy through ionization. Thus, the portion of the electron beam that is directed into the gas induces a plasma 160 (hereinafter alternatively referred to as plasma probe) in the gas where the electron beam passes through it. Aside from slow gas ions, these electron-gas collisions create low-energy secondary electrons that are free to conduct. Therefore, voltages and currents may be measured or applied through the plasma. The plasma may then act as a non-mechanical contact electrical or plasma probe. Backscattered electrons are not used to carry the voltage or current signals in the plasma probe, but can be collected using an appropriate detector for added benefit of the invention.

FIG. 1 also shows a first conductor or semiconductor 165 provided on a structure under test 170, with which the gas may be in contact. The structure under test may be supported by or implemented on a base 175. The side of the membrane and frame assembly facing the “device” or “structure under test” (outside the vacuum enclosure) may be coated with a second conductor 180, which may be a thin conductive film, as will be described in greater detail below. Gas 150 is in contact with first conductor 165 and second conductor 180. In an alternative embodiment, a portion of the vacuum enclosure surrounding the membrane or aperture through which the beam exits the enclosure may be made in conductive material or material coated with a conductive device-side film corresponding to the second conductor. In another alternative embodiment, the second conductor may be formed as a separate electrode or film that is somewhere between membrane/frame assembly 155 and the first conductor, but not necessarily attached directly to the membrane, so long as the second conductor is electrically coupled to the plasma, does not disturb the portion of the electron beam outside the vacuum enclosure, and may be attached to an inspection head 195. The vacuum enclosure, the electron beam generator, and the second conductor may be referred to as inspection head 195 that generates the plasma probe.

Second conductor 180 may be coupled to an electrical measurement device 185 or a signal source 190. A data storage and system control block 198 controls testing routines and stores measured data and is coupled to inspection head 195, electrical measurement device 185, and signal source 190. The data storage unit within data storage and system control block 198 may be coupled to the measurement device and adapted to store a plurality of data values from measurement device 185. A control unit within data storage and system control block 198 may be coupled to the data storage unit, measurement device 185, and signal source 190. The data storage unit, measurement device 185, and signal source 190 may be responsive to the control unit.

FIG. 6 is a close-up illustration for explaining the construction and operation of a pinhole aperture according to one embodiment of the invention. An aperture plate is positioned in the path of the electron beam, separating the vacuum side from the atmospheric side. The aperture plate includes a pinhole having diameter smaller than the diameter dv of the electron beam in vacuum. Consequently, the size of the pinhole controls the diameter da of the electron beam in the atmosphere. That is, the pinhole aperture defines the e-beam exiting the cathode chamber, which is a different aperture from the one used for possible differential pumping. Aperturing the e-beam leads to controlling the plasma probe diameter as well. When the pinhole aperture is used in conjunction with a membrane, the primary current from the cathode chamber is limited by the ability of the membrane to withstand the thermal dose resulting from the incident electron beam. When the pinhole is used without a membrane (i.e., in a differential pumping configuration), this limit no longer applies, though constraints are imposed on the vacuum system. The pinhole aperture decouples electron beam diameter from e-beam energy, eliminating the need for high-end electron optics.

As illustrated in FIG. 6, the edges of the aperture should be of sufficient thickness, indicated as T, to stop the incident primary e-beam where needed and to form top-hat beam profile. This produces a plasma probe with hard edges minimizing skin-depth and cross-talk from arrayed targets.

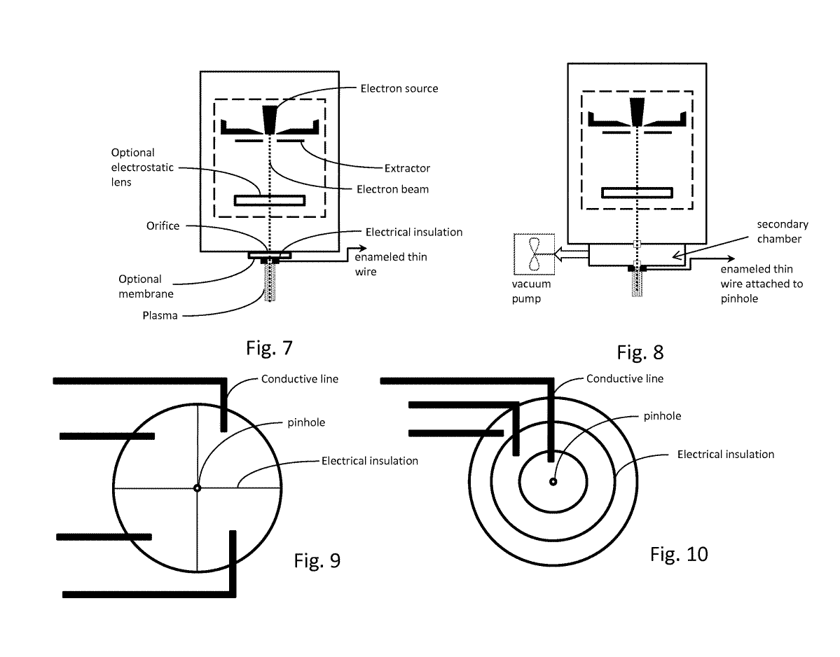

FIG. 7 illustrates an apparatus which utilizes a pinhole aperture, such as the one shown in FIG. 6. In FIG. 7, the pinhole aperture may be used with or without a membrane; however, an electrical insulation must be provided between the pinhole aperture plate and the chamber body, such that the pinhole plate is not shorted to the chamber body. An electrical wire, e.g., an enameled thin wire, is connected to the aperture plate to complete the signal path from the plasma, through the pinhole aperture plate, and to the wire.

FIG. 8 illustrates another embodiment, wherein the pinhole aperture plate is used in a secondary pumped chamber for assisting in differential pumping. In this embodiment as well, the pinhole aperture plate must be isolated from the secondary pumped chamber and an electrical wire should be connected to the plate to close the electrical path.

FIG. 9 illustrates a top view of a pinhole aperture plate that can be used in any of the embodiments described herein. As shown, the aperture plate has a small pinhole, and an electrical isolation is provided to divide the plate into four quadrants. FIG. 10 illustrates a top view of another pinhole aperture plate that can be used in any of the embodiments described herein. As shown, the aperture plate has a small pinhole, and an electrical isolation is provided to divide the plate into concentric electrically isolated circular sectors. As shown in FIGS. 9 and 10, separate conductive lines are connected to each electrically isolated sector of the aperture plate, such that the signal can be obtained separately for each sector.

### High Resolution Voltage Contrast Imaging

Voltage contrast is a failure isolation technique that is useful in isolating yield problems to a particular circuit or circuit block in IC fabrication. In the prior art voltage contrast measurements are performed by placing the sample in a vacuum chamber and charging the sample using an electron beam, following which the sample is imaged using secondary electrons. This is generally a two-step process and requires a high vacuum chamber and an elaborate electron beam source. Open vias, i.e., metal contacts that have no connection to ground, will retain the charge and appear differently on the secondary electron image than those that are connected to ground. In other words, open vias locally trap charge and change the surface voltage of the sample. This can be used, for example, to examine which contacts in an integrated circuit are closed and which are open.

According to one embodiment, a pinhole of several 10's of nm diameter is made using, e.g., lithographic technology. Using relatively short working distances between the pinhole and the DUT (10-50 um), plasma beam diameters of 50 nm and less should be achievable, while retaining sufficient e-beam current to generate plasma signals of more than 10 pA. This combination of resolution and signal levels should allow detecting defects in critical IC structures such as open gate contacts for example. Unlike conventional Voltage Contrast Imaging techniques, the e-beam induced plasma probe approach does not require a two-step measurement (pre-charging and probing) of the inspected via in order to determine whether it is open by modifying the secondary electron emission cross-section. The plasma probe can perform an open/short measurement in a single step by measuring the plasma current and comparing it to a golden reference, simplifying tool recipe and enabling throughput advantage (see FIG. 2).

The testing can be performed by scanning the electron beam, and as a consequence the plasma column, over the sample. A bias potential is applied, such that electrons from the plasma are driven into the sample. The current flow from the sample is measured through a detector connected to the metallic aperture where the primary e-beam exits the apparatus. If the feature that is being scanned is electrically connected to the common ground, current will flow and the current reading will register at the detector. Conversely, if the feature being scanned is isolated, i.e., there is an open circuit, current will not flow and the current reading would register a different value at the detector. As the resistance of the open, or partially open circuit changes, different current would flow, such that a different current reading would be obtained. These current readings can be mapped to provide a voltage contrast image of the scanned area.

The arrangement is illustrated in FIG. 2A, wherein voltage potential is applied to the electrode 180, such that electron current is driven from the plasma into the sample. A current measurement is provided in-line with the electrode, to thereby measure the current flowing into the sample 170. It should be appreciated that if the plasma probe contacts an area of the sample with many open vias, the flow of the electrons from the primary beam of the electron source may charge the sample, thereby distorting the measurement. Therefore, in some embodiments the potential applied to the electrode 180 is alternating, so as to periodically discharge the sample. This ensures that a properly fabricated feature and a defective feature would provide a different response to the voltage applied via the plasma prove, thereby enabling voltage contrast imaging.

Additionally, in FIG. 2A a gas injector 171 is used to inject a mixture of gas into the plasma so as to control the signal level and the amount of beam broadening of the electron beam by virtue of the atomic number and the density of the gasses in the mixture, which control the cross-section of the interaction between the gas mixture and the e-beam. For example, injecting helium will result in less broadening of the electron beam, but also less signal. Conversely, argon would generate larger broadening of the beam, with increased signal. Therefore, by controlling the injected gas, for example, the ratio of argon and helium in a helium and argon mixture, one can control the beam broadening and the signal level.

Note that under the appropriate sample bias, the plasma current can be up to 2 orders of magnitude larger than the incident e-beam current. This is due to the fact that a single electron in the primary e-beam current, which typically has an energy in the 5-50 keV range, undergoes a cascade of multiple random inelastic collisions, producing many secondary electrons that are sufficiently mobile to carry the plasma signal along the entire length of the probe (typically less than a few 100 microns). The plasma current can be further boosted by using a local noble gas environment (Ar, Ne, . . . ), which leads to higher ionization rates. On the other hand, with He, for example, smaller plasma diameters, i.e., higher resolutions down to several nano-meters should be achievable. The trade-off between probe resolution and conductivity can be pre-engineered in a stable manner by flooding the working space between the entry point of the electron e-beam and sample with a suitable gas mixture for a given application.

As can be appreciated, since the plasma prober can be used to perform voltage contrast inspection in an atmospheric environment, without requirement for the inspected substrate to be in vacuum, the tool according to this embodiment may be integrated into a processing tool, rather than being a stand-alone tool. For example, the plasma prober may be integrated onto an etcher or CMP tool to perform inspection immediately after processing of the wafer is completed. Additionally, the plasma prober may be installed in the front end, also called mini-environment, of a cluster tool used to process integrated circuits, e.g. for pre-mapping or alignment purposes.

Moreover, the achievable resolution of the plasma probe can be much higher than that of a conventional voltage contrast measurement system. This is because, at least in part, the lateral size of the plasma probe relative to that of the structure under test needs to be small enough to detect the differential signal between the structure and the surrounding background. Since the SNR of the plasma current is very high the plasma probe can quite large to the structure under test. Thus, the effective resolution can be reduced down to about 5 nanometers while using a plasma probe of much larger lateral size. On the other hand, secondary electron imaging as used in conventional voltage contrast measurement systems requires the incident electron beam to be smaller than the size of the structures being probed.

Furthermore, since the plasma probe does not require separate platform and vacuum, its throughput can be much higher than a standard stand-alone tool. Also, it requires a single-step illumination and imaging, while standard tools require a two-step pre-dosing and imaging process.

### High Aspect-Ratio (HAR) Structure and Deep Trench Inspection and Imaging

E-beam induced plasma probes currents are very sensitive to the separation between the pick-up electrode and the device under test. Preliminary laboratory tests demonstrated sub-micron sensitivity, but much better sensitivity can be achieved with better current detectors. The dependence of the probe column resistivity on the separation is a combination of the plasma sheath effect and the sheer Ohmic resistance due to the finite mean-free-path of the secondary electron carriers in the probe. Therefore, electron beam-induced plasma probes can be used to image and inspect high aspect ratio semiconductor features such as deep trenches and Through-Substrate Vias (TSV); see FIG. 3. HAR structure metrology is important in 3D integration and packaging of modern electronics, and also critical in high-density memory fabrication. Based on empirical observations, it is expected that height variations smaller than 1 micron can be resolved with the plasma probes. Competing technologies, such as Scanning Electron Microscopy or Atomic Force Microscopy (AFM) do not offer this capability either due to the relatively short depth of focus in the former technology (secondary electrons used in voltage contrast measurements have limited mean free path) or geometrical constraints for the latter (cantilevers used in AFM have limited travel). Optical Scatterometry is a promising alternative candidate for high aspect ratio structure imaging but is not well suited for sparse structures and highly absorptive materials like Si or metals. Note that for heterogeneous material structures (e.g. metal lines on dielectric), it might be advantageous to have some prior knowledge of the material composition or the expected topography, since the plasma current will also depend on the conductivity of the inspected materials. As such, the plasma probe signal can also be processed to produce an image of the structure under test, offering a very economical and unique imaging capability with a high resolution and a large working distance.

It should be noted that the sample need not be biased or grounded for the measurements described herein, since the current is driven from the electrode in the electron beam source. The electrode may also be the aperture for the electron beam source.

### Three-Dimensional (3D) Registration

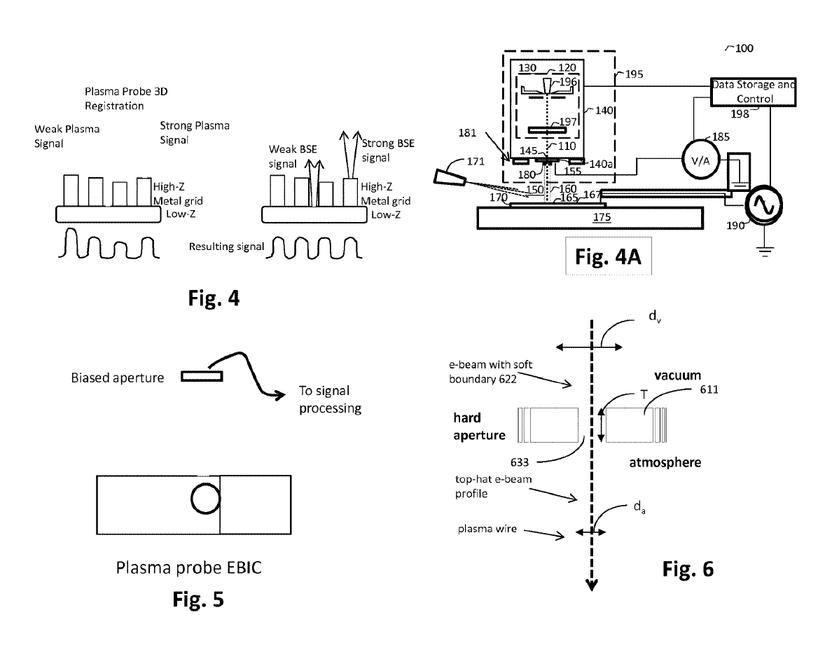

Electron beam induced plasma probes offer the unique capability of 3-D registration (see FIGS. 4 and 4A), as opposed to state of the art methods based on Back-Scattered Electrons (BSEs) which only allow for planar registration due to the low sensitivity of the BSEs to working distance. The current carried by the plasma probe is not only sensitive to the conductivity—providing lateral resolution similar to the BSE case (for which the yield depends on the atomic number of the materials under test)—but also to the distance to the device under test, as explained above. Since registration targets generally have a different composition than the material that they are deposited on (e.g. metal targets on insulator or Si), a transition from the registration target to its surroundings should give a much larger plasma current response than a mere change in profile within a given material. Prior knowledge of the nominal material compositions and/or profiles can be employed to facilitate the registration process. This entails, as an examples without limiting other manifestations, setting up configurational or compositional models of the structure under test, generating predictive signals and fitting the model to the collected signal using algorithms that produce the configuration and/or compositional metrology sought.

Since backscattered electrons (BSE) have enough energy (keV range) to propagate in atmosphere over the working distance, full 3-D registration can also be facilitated by complementing the plasma current measurements with BSE data from BSE detector 181 (e.g., an annular BSE sensor). In this case, one would use the BSE signal for lateral registration and the plasma current for vertical registration. The 3-D registration capability is important for any application in which it is critical to maintain a precise gap to the wafer and helps eliminate dependence on knowledge of wafer or glass placement on the chuck, and plasma probes should provide better Z-sensitivity than the optical sensors that are typically used in high-end sample stages. Therefore, not only do inspection and imaging applications based on e-beam induced plasma probes not require a separate registration capability; e-beam induced plasma probes may also be used as stand-alone registration capability for other applications, especially when Z-registration is important, as in flat panel inspection, profilometry, and as pre-aligner in e-beam load lock systems. This 3-D registration system can be integrated into a feedback loop to provide real-time gap control.

It should be emphasized here that unlike electron beam imaging, where the electron beam diameter must be much smaller than the feature size in order to properly register the feature, using the embodiment disclosed herein the probe diameter, i.e., the diameter of the plasma column, need not be smaller than the feature size. This is because the image is not formed using secondary or back scattered electron from the sample, but rather using current attenuation. Thus, even if the plasma column is larger than the feature size, a change in plasma current measurement indicating the edge of a feature, can still be detected when traversing said feature with the plasma probe by virtue of the high SNR of the plasma current. Thus, features much smaller than the diameter of the plasma column can be imaged.

### Impedance Mapping

As noted above, measuring the current flowing from the plasma into the sample can provide image of the sample. Changes in the image, i.e., in the measured current, are caused by convolution of topography changes and material changes (e.g., different materials having different compositions, thereby different impedances). On the one extreme, if the sample is of pure and uniform material composition, the resulting image would reflect changes in topography only. Conversely, if the sample is perfectly flat, but has areas of non-uniform material composition, the image would reflect changes in material composition only (e.g., changes in grains or doping). Note that the image is not resolution dependent, but rather sensitivity dependent, i.e., so long as the probe can detect changes in the current, the prober can generate a high resolution image even with a relatively low resolution prober. This utility of the plasma probe resistance mapping lends itself to applications in metal lines metrology, doping metrology and protrusion defects, to name a few. A combination of compositional and topographical changes may also be discerned if the collected signal can be de-convolved with the aid of a model for the samples under test using certain algorithms.

For example, one may calibrate the prober using a sample of known uniform material composition and known topography. Then the prober can be used to inspect other samples and compare to the “golden sample” to determine the material composition uniformity of the scanned sample. Conversely, the variation in topography can be mapped by similarly de-convolving the signal generated from the topography and the material impedance. Other calibrations and algorithms can be used to de-convolve a signal generated from a mixed material/topography change. For example, if the spatial scale of the signal change or the level change of the signal is outside a certain expected range, the change of the signal can be interpreted as one over the other.

### Atmospheric Electron Beam Induced Current (EBIC)

EBIC is another isolation technique which can provide more precise failure location information, typically down to 500 angstrom resolution. It is particularly powerful when performed using a probe station in an SEM. In addition to providing fine fault location resolution, EBIC has the benefit of being non-destructive with respect to the electrical and physical characteristics of the fault region.

EBIC is a technique used for buried defect inspection in semiconductor devices. The electron beam is used to stimulate the sample and generate electron-hole pairs in p-n or Schottky junctions present in the device under test, resulting in a current. In conventional EBIC, the incident electrons are generated in vacuum by means of a Scanning Electron Microscope (SEM) and the current generated in semiconductor junction is collected via physical probes at the periphery of the device. See, e.g., H. J. Leamy, “Charge Collection scanning electron microscopy,” Journal of Applied Physics, V53(6), 1982, P. R51. On the other hand, with e-beam induced plasma probe technology, the primary electrons in the probe can be used to excite the electron-hole pairs and the plasma can be used as a conductor to collect and sense this current. Thus, the probe is utilized both as stimulus and sensor.

The plasma probe presented in this invention provides better implementation of the traditional EBIC techniques. First, EBIC with electron-beam induced plasma probes can be performed in air or a controlled gas mixture in the working distance, providing advantages in system configuration, cost and throughput over SEM-based EBIC. Second, the plasma probe is more sensitive to the EBIC signal fluctuation since the current from the sample is sensed directly in-situ by the plasma probe and does not have to travel through the entire sample to probe contacts (as is the case with the conventional implementation of EBIPP, especially in large samples such as Si wafers). As such the plasma probe sensitivity to buried defects will be larger than in SEM-EBIC, especially for weak semiconductors or even for some insulators.

### Selective Surface Modification

Some applications require selective surface modifications. For example, in some application selective ashing or etching is needed. Other applications entail surface activation, passivation, wetting, functionalization or any other form of plasma-assisted surface interaction including but not limited to chemical and physical interaction. Conventionally this is achieved by means of a mask covering the areas that are not to be modified, while exposing the areas to be modified, e.g., ashed, etched or modified in any of the ways aforementioned. Plasma is then provided over the entire wafer, such that the mask provides selective contact of the plasma with selective areas of the wafer.

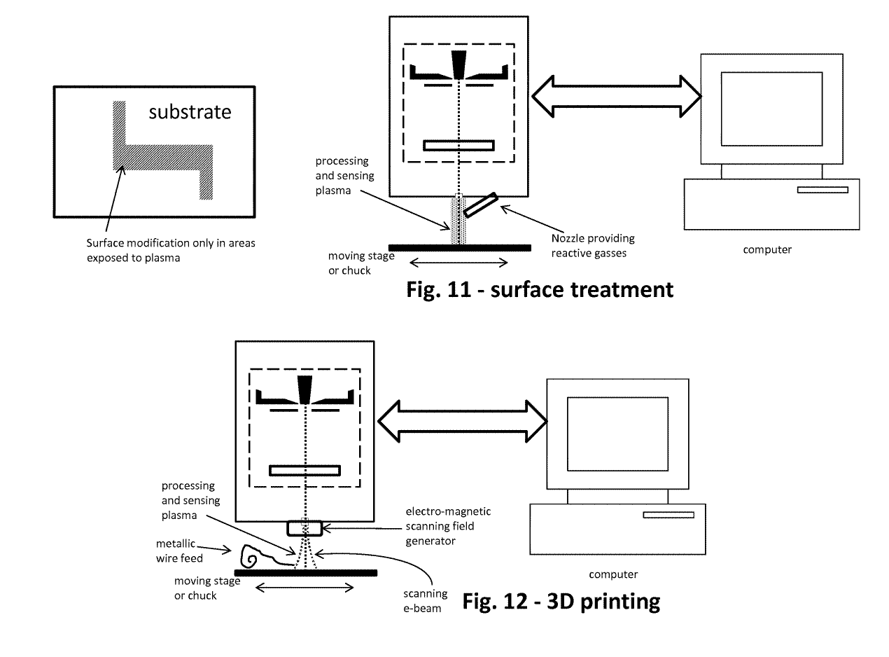

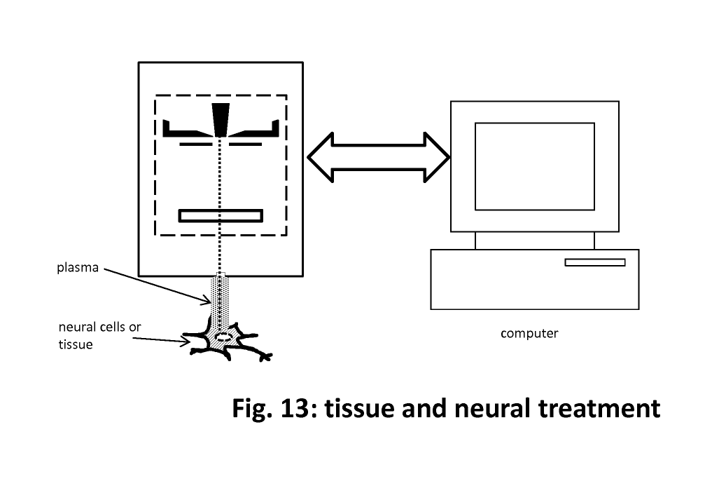

Electron beam-induced plasma probes offer the capability of performing this spatially selective processing without masks (see FIG. 11). Using certain embodiments of the invention, e.g., the embodiment illustrated in FIG. 2A, appropriate reactive precursor gases can be injected from nozzle 171, such that surface modification can be performed only in areas scanned by the plasma column. The gases may be, e.g., chlorine or fluorine gases, HBr, etc. for etch, or oxygen for ashing.

According to one embodiment, the plasma column is used for edge shunt, detection, isolation and removal in solar cells. Specifically, the plasma column is scanned around the edge of the solar cell so as to ablate the conductive layer and thereby isolate the potential shunt. The e-beam driven plasma probe can perform a closed-loop operation to treat solar cell shunts. The e-beam induced plasma probe can be used can map the impedance response after flashing a solar sample to identify shunt areas. Shunt sensing can also be performed by e-beam excitation of the solar sample and measuring the electrical or optical response of the sample, otherwise known in the prior art as Electro-luminescence or Photo-luminescence, respectively. After shunt sensing, the e-beam driven plasma probe can isolate the shunt, ablate the shunt with e-beam or etch it with the generated plasma. Sensing of the resulting treatment can then be performed and the shunt treatment process can be repeated as necessary. The advantage of the e-beam driven plasma probe over existing art (e.g., laser treatment) is the closed-loop and all-in-one operation along with the spatial selectivity of the plasma probe.

Embodiments described herein utilize plasma creation by e-Beams with energies in the keV range. Gas mixtures can be introduced in the space between source and sample and ionized by the e-beam, providing a wider range of reactive chemistry.

Electron beam-induced plasma probe technology has a number of advantages over other technologies used for plasma-assisted surface modification. For instance, with electron beam-induced plasmas, there is no risk of contamination, as opposed to what may occur with DC discharge plasma-based systems, in which the electrode can evaporate. In general, electron-beam induced plasmas involve much lower temperatures than DC discharge plasmas since the energy of the plasma electrons at the target is on the order of a few eV. Moreover, no air flow is required to convey electron-beam-induced plasmas to the target (since the plasma follows the direction of the primary beam), as opposed to RF discharge-induced plasmas.

The lateral dimension of the e-beam incident in the ionizing medium, and hence that of the resulting plasma, can be scaled down to 100 nm or lower by means of hard apertures or—at higher costs—by focusing the beam using the appropriate electron optics elements. This implies that electron beam-induced plasmas enable spatially selective surface modifications with submicron resolution. Such resolutions are not possible with other plasma-assisted surface modification methods since aperturing beyond a certain limit will lead to catastrophic turbulent flow and would significantly limit the efficiency of the plasma. To our knowledge, the existing resolution of the concurrent gas-backed atmospheric plasma technology is not better than 1 mm. The high resolution capability of electron beam-induced plasma probes make them a good candidate for (subtractive) maskless patterning applications as used e.g. in MEMS, in-situ patterning on polymer surfaces and 3D printing.

Electron beam-induced plasmas can be tuned over a wide range of parameters (beam current, spot size, energy, ambient gas, working distance, etc. . . . ). As a consequence, electron beam-induced plasma probes can be used in a number of different ways. For instance, by setting the parameters of the electron beam-induced plasma appropriately, the plasma probe can be configured to either sense or process. This could allow the probe to be used for surface composition sensing, followed by surface modification and subsequently for post-process sensing to assess the impact of the modification. This in-situ sensing capability in turn should allow closed loop processing—substrates do not need to be taken out of the processing tool for metrology, reducing contamination, improving yield and allowing for the development of more efficient process recipes. Furthermore, different gas ambients can be used to allow different surface reaction chemistries. Moreover, both the plasma and the primary beam can be operative to modify the surfaces, giving access to processing powers ranging from a few to hundreds of Watts.

### Spatially Resolved Surface Modification

The use of plasma in the treatment of surfaces may be employed in multiple industries. Among the main applications of plasma in the treatment of surfaces are cleaning (specifically, the removal of organic contaminants), adhesion enhancement by generation of polar groups and wettability modifications. Many of these processes can be carried out in atmosphere using the disclosed embodiments, thereby avoiding the use of a dedicated and often costly vacuum chamber and eliminating the corresponding infrastructure and throughput drawbacks.

The free electrons, ions, radicals and UV radiation generated in a plasma can break covalent molecular bonds, which in turn can result in ablation (as in the cleaning application), cross-linking to free radicals in other polymer chains, facilitating adhesion, and activation (replacement of polymer functional groups by chemical functional groups or atoms from the plasma). With regards to the latter, atmospheric plasmas in particular contain a high density of reactive (oxidizing) species that facilitate the formation of polar groups, such as C—N, O—H (hydroxyl), C—O, O—C═O and C═O (carbonyl), HOOC (carboxyl) and HOO— (hydroperoxide), as can be verified by X-ray Photoelectron Spectroscopy (XPS). These polar groups promote strong covalent bonding between the substrate and its interfaces, e.g. fluids, leading to improved wettability and adhesion.

In certain disclosed embodiments, plasma-induced micro-roughing (as a result of ion bombardment and/or by chemical etching) can also improve bonding adhesion. Furthermore, the impact of the plasma treatment depends strongly on the gas environment as well as the treated substrate. For instance, fluorine plasmas (e.g. based on a CF4 ambient) can be used to make a polymer surface hydrophobic instead of hydrophilic. Inert gas plasmas (such as Ar or He) are more appropriate for surface cleaning (by ion bombardment/ablation of contaminants). Finally, N2-rich atmospheric plasmas can be very effective in making Cyclo-Olefin Copolymer (COP) hydrophilic and hemocompatible (the latter is important for medical applications).

Many applications, in particular microfluidic devices used for e.g. DNA analysis, point-of-care diagnostics, but also certain bonding applications, require spatially selective surface modification. In general, microfluidic devices consist of one or more pre-patterned channels in which fluids are transported. Plasma treatment can enable and promote the flow of fluids through the channels, but in order to prevent the fluids from exceeding the channels and to constrain the fluid flow only to the targeted channels, the surface of the device cannot be treated uniformly. Channel widths range from sub-microns to several mm. Since existing plasma treatment methods cannot meet these resolution requirements (even plasma jet pencil systems cannot reach <1 mm and entail gas flows that may generate turbulences and damage the device under process), spatially selective plasma treatment is generally accomplished by means of techniques such as lithography or masking.

The selective surface modification in the eBIP system concept is performed through the combined action of the driver e-beam and the plasma it induces. There are types of surface modification that the e-beam itself induces, simultaneous with the plasma action. In addition, an external material can be introduced to the treated area to induce time-limited or permanent surface modification. This external material could be metallic or non-metallic, conductive or insulative, organic or non-organic. The materials could be provided in extruded form, in wire-like form, in powder form, in nano-particle form, and in liquid or gaseous form. These could be additive or subtractive. As an example for combined e-beam plasma action on a surface, fine conductive powder or nano-metallic particles can be introduced to a non-conduction substrate where suitable plasma chemistry acts to prepare the surface of the sample for bonding while the e-beam melts and fuses the conductive material to the surface. This process generates permanent conductive tracks on the substrate surface; this technique can be used to generate Printed Circuit Boards (PCB) or to modify existing tracks on the substrate. The surface modification can also be repeated on the same location with the introduction of external material leading to what is known as 3-D printing, or additive manufacturing. In a similar action on the substrate surface, the combined action of the e-beam and plasma can modify the substrate surface by subtracting material, for example, the conductive tracks mentioned above can be ablated by the e-beam and the plasma many play the role of cleaning the surface from desorbed deposits making the e-beam driven ablation process of the conductive lines faster.

The process of selective surface modification by way of adding or subtracting material, also known as 3-D printing, can yet be performed at sub-micron resolution comparable or better than laser sintering or stereolithography.

The plasma treatment system is based on a new spatially selective surface modification technique using electron-beam induced plasmas. This technique is based on ionization of the ambient gas (atmosphere or other controlled mini-environments) by an electron beam traversing through it. Some embodiments rely on sending a medium energy electron beam in the keV regime from the vacuum enclosure in which it is generated though a thin, electron-transparent membrane (e.g. 100 nm SiN) or a differentially pumped pinhole into the surrounding ambient. Since plasmas created this way are confined to a (narrow) cylindrical volume around the e-beam, it provides intrinsic spatial selectivity without requiring further processing such as lithography or masking. This greatly simplifies the plasma treatment process and reduces the associated costs. Plasma diameters as small as 13 μm have been demonstrated using this technique, and smaller diameters—1 μm and below—should be possible by reducing the e-beam spot size (currently 5 μm) or aperturing the e-beam.

Furthermore, the e-beam induced plasma (eBIP) technology offers the following additional advantages in surface treatment over the existing technologies:

In addition to selectively processing pre-patterned microfluidic channels, eBIP technology can also be used to define “virtual” channels, i.e., for example, regions of increased wettability, on un-patterned substrates. This capability further reduces device fabrication costs, as it can reduce or even eliminate the need for pre-patterning channels.

Existing low-pressure (no-atmospheric, controlled gas ambient) plasma treatment platforms rely on a chamber where a flowing gas is ionized and purged onto a sample inside the chamber. This scenario requires flushing gases into the entire system which incurs consumption of large amounts of gas especially if gases need to be used alternately. The eBIP system, however, requires only introducing small amounts of gas externally into the working distance through micro-nozzles (see details below). This facilitates the introduction of eBIP technology in-line into and existing industrial process.

The eBIP system produces low power plasmas that are energetic enough to drive active surface chemistry but yet cold and safe to handle. At electron beam energies of 10 keV and currents of 10 □ A the system output is in the mW regime. The eBIP system has also high plasma conversion efficiency. For example, simulation shows that more than 95% of 10 keV e-beam energy is converted into plasma with 1 mm gap form the source

eBIP technology provides self probing of the treated surface by the driving e-beam as it excites the surface optically when the e-beam knocks off the substrate electrons that recombine emitting characteristic radiation of the surface physical and chemical conditions. This can provide real-time optical monitoring of the surface properties. Another implementation of the surface excitation is through X-rays or UV radiation generated in the plasma itself. It is also possible that the substrate emits characteristic electrons. This feature enables real-time re-treatment or dose adjustment

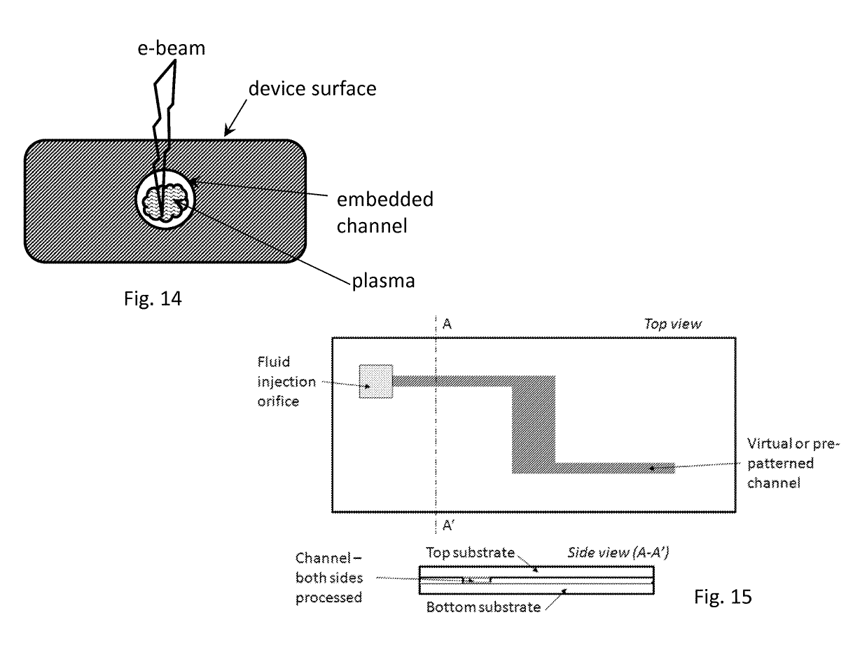

FIG. 14 illustrates the eBIP treatment of embedded (i.e., sub-surface) micro-channels, which can, for instance, be formed in dielectric thin films over narrow trenches in a silicon substrate. These microchannels can be used to flow liquids for biological testing. If the thickness of the layer in which the embedded micro-channels are fabricated is thin enough (typically less than a few hundred nm), and the energy of the e-beam is high enough (>30 keV), the e-beam can penetrate through the surface of the film and ignite and sustain a plasma inside the channels. If the proper gas is present inside the channels, this will result in inner-surface treatment when the proper gas is present. Note that the fabrication process of embedded channels in the microfluidics domain is usually involved, and in some special applications, comparable to Integrated Circuits (IC) fabrication, thus attempting to treat the channels during fabrication is not possible. As such, this embodiment provides a solution for treating embedded channel since the driving e-beam can penetrate the substrate surface while maintaining its spatial confinement. The e-beam may spread out as it propagates through material, but this broadening can be pre-compensated for.

The feasibility of spatially selective surface modifications by e-beam induced plasmas was demonstrated on various polymers, Silicone and glass substrates, which showed substantial improvements of high surface tension fluid flow in channels of microfluidic devices after treatment, without spillage outside the processed areas and with lifetimes of at least a week. This was accompanied by a significant reduction of the fluid contact angle. Furthermore, the plasma treatment enabled the fluid flow in narrow channels (<100 microns) that otherwise did not flow. The eBIP surface treatment chemistry can scale down to sub-micron channel widths

Note that many microfluidic devices consist of a bottom substrate, in which pre-existing or virtual channels can be defined, and a top substrate (with openings to introduce the fluid under test) acting as a cover. In order to obtain optimal capillary fluid flow in such devices, the top substrate should be processed by eBIP with a pattern matching the one on the bottom substrate—see FIG. 15.

Not only is the eBIP treatment spatially selective, it also provides high-throughput. The driving e-beam source used for the spatially selective plasma treatment system may have a programmable deflection capability as well as multiple simultaneously operating columns or emitters, by flooding or back-illuminating a divergent e-beam on a pre-patterned shadow mask or a mask with multiple apertures. Furthermore, the beam may be driven in pulsed or continuous mode for better control and tuning of the dose.

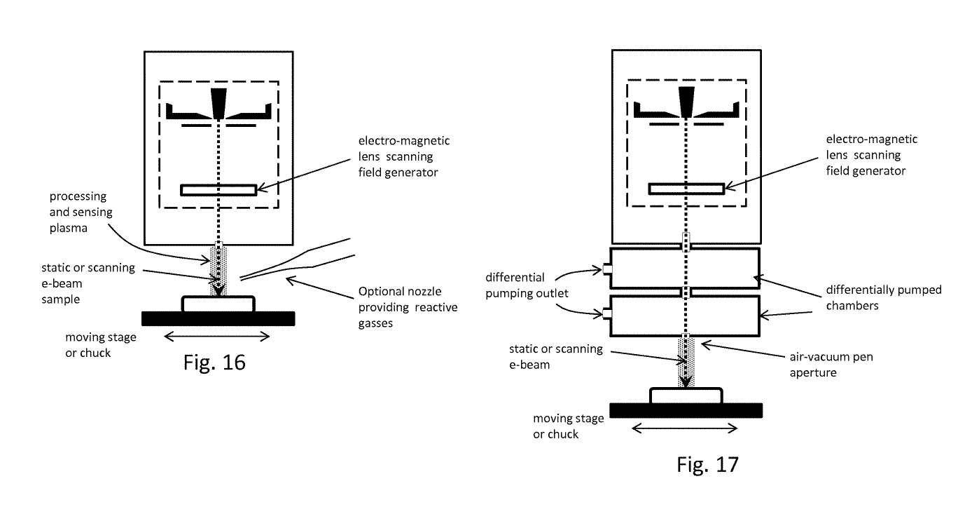

In the system illustrated in FIG. 16, the electron beam includes a stage assembly that moves the device under process laterally relative to the e-beam induced plasma. In various embodiments the relative displacement may be achieved either by moving the device while the beam is fixed or by moving the e-beam while the device is fixed, or a combination thereof. For example, the system illustrated in FIG. 16 includes electromagnetic scanning lens to scan the beam. For example, the stage may be used for large displacement scanning while the electromagnetic lens may be used for small displacement scans. The aforementioned stage assembly can have a gantry or split-axis architecture, and the devices under process can be positioned on a flat support such as a vacuum chuck.

In some embodiments the e-beam sources could also be mounted on a vertical (Z-) stage so that the distance of the source relative the device under process can be varied. This distance can be monitored by a separate sensor (e.g. a laser triangulation sensor) or by measuring the secondary electron current in the plasma itself (this requires a thin conductive layer on the membrane to collect the secondary electron current and some level of conductivity of the substrate), since this current is strongly correlated to the working distance. The latter capability could in principle allow real time tracking—and adjustment to—surface topography. Note that the system on which the e-beam sources area mounted could be a dedicated system or system that is also used for other purposes. Alternatively, the plasma treatment head can be mounted on a moving robotic arm that performs surface treatment on a highly 3-dimensional object.

The motion path can be programmed in the stage controller according to the layout of the device. Registration of the plasma to the device under process can be done optically by means of a dedicated optical alignment assembly, using registration marks on the devices (in this case the lateral offset between the plasma and the optical alignment assembly needs to be calibrated separately). Alternatively, the secondary electrons in the plasma can be used to register the plasma; this requires alignment features with topographical or material contrast. The plasma treatment of the sample can be monitored optically by machine-vision system mounted above or below the sample.

In order to achieve high throughputs, it is beneficial to continuously scan the stage/device, though a step and repeat motion (or a combination of scanning and stepping) is also possible. In addition, systems can incorporate multiple e-beam assemblies, allowing the treatment of multiple devices in parallel. E-beam sources with multiple emitters can also be used to decrease overall process time. Furthermore, structures that are significantly larger than the largest obtainable plasma diameter in the direction parallel to the motion of the stage/sample can be obtained by deflecting the beam laterally with respect to the motion of the stage/device (instead of treating the wide structure with multiple passes). However, it should be noted that for channels <1 mm or so, this should not be required as the plasma diameter can be adapted to the structures under process by varying the working distance and/or the beam energy. This adaptation can be done on the fly using the Z-stage, based on the device layout information supplied to the system controller. The plasma diameter in general is determined by the initial e-beam diameter entering the atmospheric working distance; the e-beam diameter can be further controlled by an extended electromagnetic field in this gap. The dose of the driving e-beam which in turn determines, among other parameters, the plasma density is usually limited by the thin membrane breaking limit and thermal loading. However, a system can be configured that comprises a final open aperture and multiple chambers that are differentially pumped to keep the pressure inside the gun system at the requisite operational level. See FIG. 17. This system should mitigate the limit on the current dose.

In order to obtain different types of surface chemistries, the e-beam head can be outfitted with one or more micro-nozzles supplying different gas (mixtures). These nozzles should be mounted in close proximity to the point of entry of the e-beam into atmosphere. This approach avoids the use of a separate vacuum chamber, though it may be desirable to have an evacuation capability close to the nozzle to siphon off unwanted excess gas and residue. Several surface treatments can be combined using a multi-nozzle local gas supply; for instance, cleaning using and Ar plasma, hydrophillization of selected areas using an O2 plasma and hydrophobization of other areas using a CF4 plasma.

Aside from the gas ambient, the system offers the capability of controlling the exposure time by e.g. controlling the dwell time using the stage scan speed and/or the beam pulse duration. Beam pulsing may also be used to control the heating of the substrate (which in turn impacts the aging behavior of the surface modification). Other parameters that can be used to control the surface modification process are the beam energy and current, as well as the working distance as discussed above.

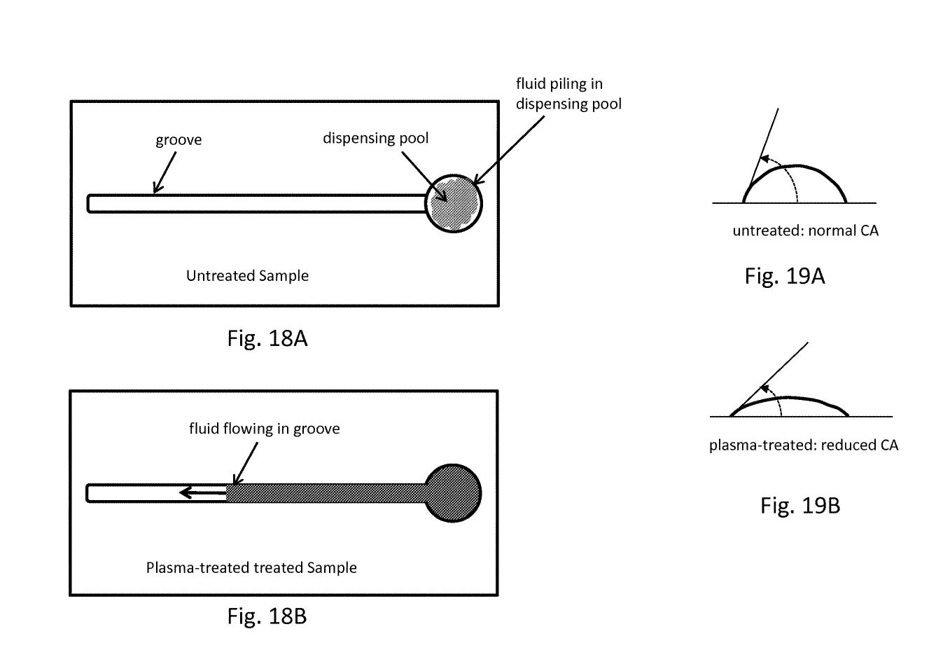

FIGS. 18A and 18B illustrate a simple microchannel substrate for flowing fluids therein. FIG. 18A illustrates the situation prior to plasma treatment, wherein due to surface tension the injected fluid simply accumulates at the dispensing opening, but fails to flow through the channel. FIG. 18B illustrates the situation after plasma treatment, wherein the fluid propagates through the treated channel. FIGS. 19A and 19B illustrate a test done of a flat substrate having no channels cut therein. FIG. 19A is a trace of a drop of ink placed on the untreated area of the substrate. As shown, the rather large contact angle is form by the fluid. FIG. 19B is a trace of a similar ink drop placed on an area treated by the plasma using the disclosed embodiments. Consequently, the surface wettability is increased and the contact angle decreased.

In various testing of the disclosed embodiments, clear improvements in, and equal distribution of, fluid flow in MF channels exposed to eBIPs was demonstrated. Using X-ray Photoelectron Spectroscopy (XPS) a significant addition of hydrophilic functional groups after eBIP exposure was detected.

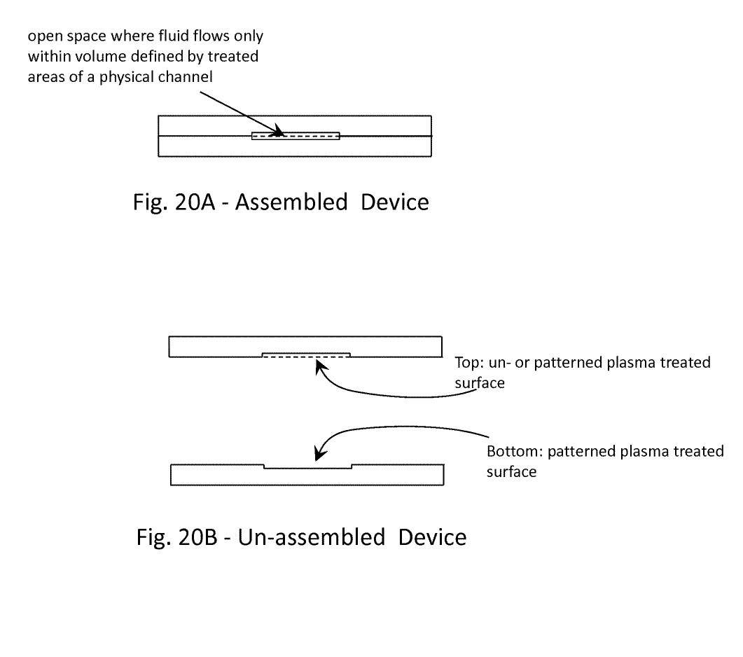

FIGS. 20A and 20B illustrate a microchannel device wherein a physical channel is formed, and then treated using the eBIP. The channel is formed on at least one of the plates. For example, in one embodiment the channel is formed on the bottom plate only. Then the channel is treated by the eBIP and the corresponding area of the top plate (which is not patterned) is also treated with eBIP. Then the two plates are adhered together to form the device. According to another embodiment corresponding channels are formed on both the bottom and top plates, and both channels are treated with eBIP.

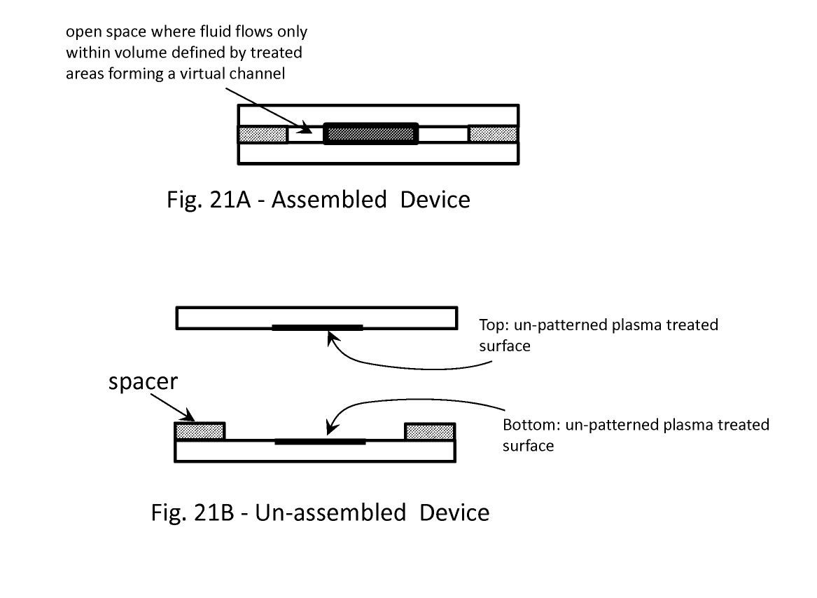

FIGS. 21A and 21B illustrate an embodiment wherein “virtual” channels are formed. Specifically, both top and bottom plates are flat without any physical channels formed therein. Then, the specific shape of the desired channel is “written” on both top and bottom plates by simply tracing the desired design one the plates using the eBIP. The eBIP tracing does not form an actual physical channel, but changes the wettability of the plates at the traced surfaces. The two plates are then adhered together with a spacer placed in between. When fluid is injected into the device, the fluid will flow and be confined to the treated tracing only, thus forming a virtual channel.

In various testing it was determined that the eBIP treatment causes increase in oxygen concentration at the surface of the plates, which is consistent with results obtained with low pressure plasma treatment. The oxygen concentration was observed to remain stable as function of post-treatment delay, suggesting a persistent change. Also, the oxygen is roughly equally incorporated in C—O and C═O groups.

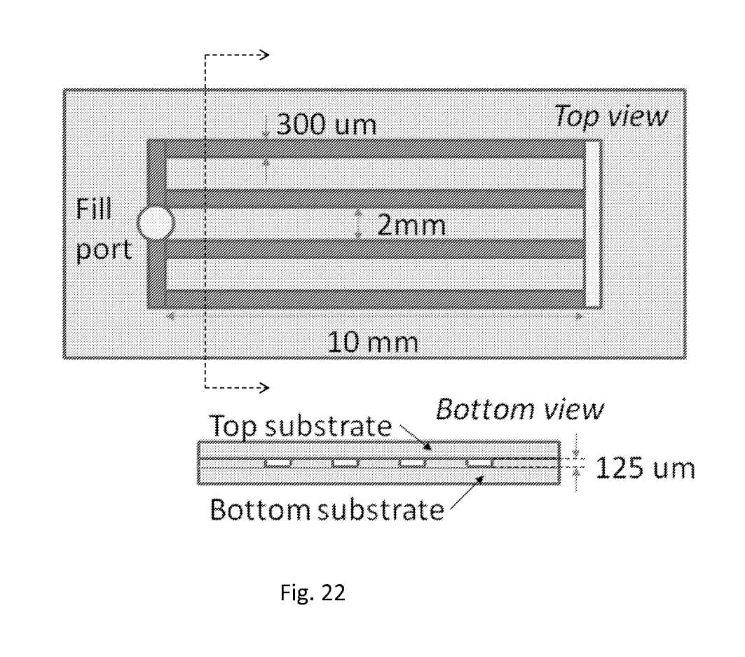

FIG. 22 illustrates another microchannel device having a single point of fluid injection and a plurality of channels. The single point of injection and the plurality of channels have been treated with eBIP. The treatment of the injection point and channels using eBIPs demonstrated clear, reproducible improvements in fluid flow without requiring masking by localized attachment of hydrophylic functional groups. The eBIP embodiments can also used to define channels on unpatterned substrates, as illustrated in FIGS. 21a and 21B, further decreasing manufacturing costs.

### 3-D Printing:

Owing to the micron-level resolution, the plasma probe can be used for metal deposition in high-resolution 3-D printing applications, as illustrated in FIG. 12. The plasma probe apparatus proposed in this invention, operating at primary e-beam energy of tens of keV, is suitable for high-resolution 3-D printing, especially with metals. Since most metals have an e-beam stopping power around 10 keV/micron, small metal wires or sputtered metal particles can be melted on a surface using the primary e-beam operating in air at small working distance (on the order of 10 microns), over which the loss of electron energy is small. The advantages of the e-beam driven plasma probe system over existing e-beam 3D printing techniques like free-form fabrication or direct e-beam melting are the following: it can be performed in atmospheric conditions, the plasma probe can serve as in-situ tool for surface preparation like activation to improve the quality of melted metal adhesion and reduce the e-beam dose, and the electrically conductive probe can be used to drain the deposited charge from the driver e-beam resulting in an electrically neutral printing process.

The plasma probe can be also used as an in-situ sensor for post printing verification. This provides a closed-loop printing function. The e-beam operating parameter space for melting and sensing are different, as one might expect. For example, the beam current used for printing should be adjusted to provide for uniform thermal dose deposition on metal to insure uniform melting and adhesion rate, while the sensing action is done at smaller current enough to merely drive a conducing non-mechanical contact (plasma) probe to the surface. This action can be repeated point-by-point or line-by-line either by scanning the e-beam or by a moving stage where the printed sample is placed. An extended layer can then be formed and layers can be stacked vertically to complete the 3D printing function.

The most likely embodiment of a 3D printing device based on this invention is one in which the e-beam printing head is controlled by a computer that can load Computer Aided Drawing (CAD) designs with standard format and implement them. The e-beam printing head can be used as a stand-alone or complimentary head to another 3D printing head that uses conventional, state-of-the-art 3D printing techniques; e.g. plastic fused deposition or laser melting. A further advantage of the atmospheric e-beam system is that it can perform additive printing per the above description as well as subtractive printing, since the e-beam can be used to perform high-resolution ablation over small areas, especially with non-metallic materials.

### Medical and Biological Applications

The properties of electron beam induced plasma probe, specifically their low temperature, high resolution and tunability (to sensing or processing conditions), make them uniquely suited for therapeutic applications such as sterilization and decontamination (e.g. in oxygen atmosphere), blood coagulation and wound cauterization (healing), as well as cancer cell treatment. Other applications include dendrite and neuron probing, for which spatial selectivity is an important property.

In the foregoing specification, specific exemplary embodiments of the invention have been described. It will, however, be evident that various modifications and changes may be made thereto. The specification and drawings are, accordingly, to be regarded in an illustrative rather than a restrictive sense.

1. An atmospheric plasma apparatus, comprising:
a vacuum enclosure having an orifice at a first side thereof;
an electron source positioned inside the vacuum enclosure and having an electron extraction opening;
an extractor positioned at the vicinity of the extraction opening and configured to extract electrons from the electron source so as to form an electron beam and direct the electron beam through the orifice, wherein the electron bean is configured to have a diameter smaller than diameter of the orifice;
an aperture plate positioned so as to cover the orifice, the aperture plate being electrically conductive and having a conductive line attached thereto, and wherein the aperture plate has an aperture of diameter smaller than the diameter of the electron beam such that the aperture plate reduces the diameter of the electron beam as it passes through the aperture; and,
wherein the electron beam is configured to ionize the atmosphere as it exits the aperture so as to sustain a column of plasma.

2. The atmospheric plasma apparatus of claim 1, further comprising an electrical insulation member configured to electrically isolate the aperture plate from the vacuum enclosure.

3. The atmospheric plasma apparatus of claim 1, further comprising a membrane positioned between the aperture plate and the first side of the vacuum enclosure.

4. The atmospheric plasma apparatus of claim 1, further comprising a differential pumping chamber attached to the first side of the vacuum enclosure and wherein the aperture plate is attached to a lower portion of the differential pumping chamber.

5. The atmospheric plasma apparatus of claim 1, wherein the aperture plate comprises a plurality of electrically isolated sectors, each coupled to a respective conductive line.

6. The atmospheric plasma apparatus of claim 1, further comprising an electrostatic lens situated inside the vacuum enclosure.

7. A method for performing voltage contrast imaging of a sample, comprising:
extracting an electron beam from an electron source in a vacuum enclosure;
transmitting the electron beam from the vacuum enclosure into an adjacent ambient gas to thereby ionize gas molecules around the electron beam to generate a column of ionized species;
scanning the electron beam over a selected area of a sample located opposite the entry point of the electron beam into the gas ambient;
applying a voltage potential across the plasma so as to drive an electron current from the sample to a pick-up electrode;
measuring the amount of electron current flowing between the pick-up electrode and the sample;
generating an image using the amount of electron current measured at each location on the selected area and displaying the image on a monitor.

8. A method for performing three dimensional registration using an electron-beam induced plasma probe, comprising:
extracting an electron beam from an electron source in a vacuum enclosure;
transmitting the electron beam from the vacuum enclosure in to an adjacent gas ambient to thereby ionize gas molecules around the electron beam to generate a column of ionized species defining a plasma probe;
scanning the plasma probe over a selected area of a sample located opposite the entry point of the electron beam into the gas ambient applying a voltage potential across the plasma so as to drive an electron current from the sample to a pick-up electrode;
measuring the amount of electron current flowing between the pick-up electrode and the sample;
measuring back scattered electrons scattered from the sample;
using the measurement of back scattered electrons to determine lateral registration of the plasma probe;
using the measurement of the electron current to determine the vertical registration of the plasma prober.

9. The method of claim 8, further comprising using prior knowledge of at least one of material composition and topography of the sample for more accurate registration.

10. The method of claim 8, wherein three dimensional registration using electron beam induced plasma probes is used as registration capability in conjunction with electron beam induced plasma probe based processing or measurement applications.

11. The method of claim 8, wherein three dimensional registration using electron beam induced plasma probes is used as registration capability in conjunction with LCD Array testing using a voltage imaging optical system.

12. The method of claim 8, where the lateral dimension of the electron beam induced plasma is larger than that of the registration features.

13. A method for inspecting a sample using electron beam induced plasma probes, comprising:
extracting an electron beam from an electron source in a vacuum enclosure;
transmitting the electron beam from the vacuum enclosure in to an adjacent gas ambient to thereby ionize gas molecules around the electron beam to generate a column of ionized species defining a plasma probe;
scanning the plasma probe over a selected area of a sample located opposite the entry point of the electron beam into the gas ambient;
applying a voltage potential across the plasma so as to drive an electron current from the sample to a pick-up electrode;
measuring amount of electron current flowing between the pick-up electrode and the sample;
de-convolving changes in the measurement of the electron current caused by the sample;
using the de-convolved changes in the measured electron current to determine at least one of: changes material composition and changes in topography of the sample.

14. The method of claim 13, further comprising using prior knowledge of material composition of the sample to determine topography.

15. The method of claim 13, further comprising:
measuring the amount of electron current flowing from the plasma into the sample or vice-versa;
de-convolving changes in the measurement of the electron current caused by topography of the sample;
using the de-convolved changes in the measured electron current to determine changes in material composition of the sample.

16. The method of any of claim 13, further comprising passing the electron beam through a diameter limiting aperture prior to scanning the electron beam.

17. The method of claim 16, further comprising applying bias to the sample and the diameter limiting aperture.

18. A method for edge shunt detection, isolation and repair in a solar cell, comprising:
extracting an electron beam from an electrons source;
exciting the solar sample with the e-beam and measure the sample optical and electrical response.

19. The method of claim 18, comprising maintaining plasma using the e-beam to generate a plasma probe and measuring impedance of the solar cell locally using the e-beam plasma probe, and detecting shunts based on the measured impedance.

20. The method of claim 19, further comprising scanning the electron beam over peripheral area of the solar cell so as to ablate material at the peripheral edge of the solar cell at the location of the detected shunt.

21. A method for modifying surface characteristics of a sample, comprising:
extracting an electron beam having a defined diameter from an electron source;
transmitting the electron beam from the vacuum enclosure in to an adjacent gas ambient to thereby ionize gas molecules around the electron beam to generate a column of ionized species forming a plasma probe;
manipulating lateral dimension of the electrons beam as it exist into the gas ambient;
scanning the plasma probe over selected area of the sample so as to modify the surface characteristics of the sample.

22. The method of claim 21, wherein the surface modification comprise one of ashing, etching, surface activation, passivation, wetting, and functionalization.

23. The method of claim 22, further comprising using precursor gasses to modify surface chemistry of the sample.

24. A method for treatment of live tissue, comprising:
extracting an electron beam having a defined diameter from an electron source;
transmitting the electron beam from the vacuum enclosure into an adjacent gas ambient to thereby ionize gas molecules around the electron beam to generate a column of ionized species;
manipulating the lateral dimension of the electrons beam as it exist into the gas ambient;
directing the plasma ionized species over selected area of the live tissue.

25. The method of claim 24, wherein the treatment comprises one of therapeutic application, sterilization, decontamination, wound healing, blood coagulation, cancer cell treatment.
